(19) United States
(12) Patent Application Publication
(10) Pub. No.: US 2008/0222500 A1
(43) Pub. Date: Sep. 11, 2008

(54) Data relay apparatus, data relay method and data relay integrated circuit

(75) Inventors: Nana Tsukamoto, Kawasaki (JP); Tomoharu Muro, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/073,711

(22) Filed: Mar. 7, 2008

(30) Foreign Application Priority Data
Mar. 8, 2007 (JP) 2007-058743

(51) Int. Cl. H03M 13/03; G06F 11/00

(52) U.S. Cl. 714/807; 714/E11.001

(57) ABSTRACT

According to an aspect of an embodiment, a data relay apparatus for transferring writing data and an associated check code sequentially sent from a host into a memory device, said writing data containing a plurality of fields classified by the kind of information in said writing data, comprising: a memory for storing said writing data and said check code for checking an error of said writing data; a calculating module for calculating said check code to determine whether the writing data sent from the host contains an error; a transfer module for transferring the writing data into the memory, the transferring of the writing data into the memory being initiated before determination by the calculating module.

### TECHNICAL FIELD

An aspect of embodiment relates to a data relay integrated circuit in a data relay apparatus for relaying data transmitted and received between a computer apparatus and a storage apparatus via a temporary storage section, and to the data relay apparatus and a data relay method.

### SUMMARY

According to an aspect of an embodiment, a data relay apparatus for transferring writing data and an associated check code sequentially sent from a host into a memory device, said writing data containing a plurality of fields classified by the kind of information in said writing data, comprising: a memory for storing said writing data and said check code for checking an error of said writing data; a calculating module for calculating said check code to determine whether the writing data sent from the host contains an error; a transfer module for transferring the writing data into the memory, the transferring of the writing data into the memory being initiated before determination by the calculating module.

### BRIEF DESCRIPTION OF THE DRAWINGS

FIG. 1 is a diagram showing an example of a setting of a descriptor in the related art;

FIG. 2 is a diagram showing an example of CCWs in the related art;

FIG. 3 is a diagram showing a feature of the aspect of the embodiment;

FIG. 4 is a block diagram schematically showing a structure of a disk array apparatus according to an exemplary the aspect of the embodiment;

FIG. 5 is a diagram showing a data format used for transferring data to a cache memory;

FIG. 6 is a block diagram showing an internal structure of a channel adapter according to the exemplary the aspect of the embodiment;

FIG. 7 is a block diagram showing a structure of a protocol DMA chip according to the exemplary the aspect of the embodiment;

FIG. 8 is a diagram showing an example of a setting of a descriptor according to the exemplary the aspect of the embodiment;

FIG. 9 is a diagram showing an example of a descriptor format according to the exemplary the aspect of the embodiment;

FIG. 10 is a sequence diagram showing a data transfer process based on a plurality of CCWs according to the exemplary the aspect of the embodiment; and

FIG. 11 is a sequence diagram showing a data transfer process based on a plurality of CCWs in the related art.

### DESCRIPTION OF THE PREFERRED EMBODIMENTS

The aspect of the embodiment relates to a data relay integrated circuit in a data relay apparatus for relaying data transmitted and received between a computer apparatus and a storage apparatus via a temporary storage section, and to the data relay apparatus and a data relay method, the data relay integrated circuit including a transmission section for temporarily accumulating, in an accumulation area, write data that is divided into predetermined units and that is sequentially transmitted from the computer apparatus to the storage apparatus, verifying the write data on the basis of first verification data attached to the write data, determining second verification data on the basis of the write data to add the second verification data to the write data, and transmitting the write data to the temporary storage section according to a transmission instruction issued from a control device of the data relay apparatus. In particular, the aspect of the embodiment relates to a data relay integrated circuit, a data relay apparatus, and a data relay method for improving a data relay processing performance through efficient processing.

With the recent increase in the processing performance of computers, computers have been using an increasing amount of data, and a large number of studies on storage devices for storing a huge amount of data have been conducted. Specifically, for example, a technique called a redundant array of inexpensive disks (RAID) technique for realizing a high-speed, large-capacity, and high-reliability disk system by combining a plurality of hard disk drives has been developed.

In disk systems such as RAID systems, a disk array apparatus having a plurality of disks for storing data receives a command from a high-order apparatus such as a host computer, and writes or reads data. Data exchanged between the host computer and each of the disks is also cached in a cache memory provided in the disk array apparatus. In subsequent processing, the data is generally read from the cache memory for speed-up. The host computer is connected to a channel adapter provided in the disk array apparatus, and the channel adapter executes data transfer between the host computer and the cache memory or each of the disks.

The channel adapter includes a direct memory access (hereinafter referred to as “DMA”) chip such as a large-scale integration (LSI) chip for controlling DMA-based data transfer, and the DMA chip transfers data according to a data transfer instruction (descriptor) from a central processing unit (CPU). That is, upon receiving a descriptor, the DMA chip transmits and receives data whose address and data length are specified by the descriptor to and from the cache memory or the like via a bus.

Write data that is divided into a plurality of frames and that is transferred from the host computer to the channel adapter is temporarily stored in a data buffer provided in the channel adapter. The transferred frames of write data are not always stored in consecutive addresses, and are generally stored in discontinuous addresses. This is because write data is stored in an area that is not occupied at the time when it is transferred.

As disclosed in Japanese Unexamined Patent Application Publications No. 2006-40011 and No. 2002-23966, a series of write data sequences transferred from the host computer to the channel adapter has a check code. Upon receiving all the write data, the channel adapter verifies the integrity of the check code and the write data to confirm that no tampering has occurred during the data transfer from the host computer to the data buffer in the channel adapter.

As disclosed in Japanese Unexamined Patent Application Publication No. 2002-23966, the write data divided and stored in the data buffer of the channel adapter is transferred to an address area of the cache memory after all the data has been obtained and the integrity of the obtained data has been verified. Write data has a cyclic redundancy check (CRC) code based on the write data. The use of the CRC code ensures the integrity of the write data transferred to the address area of the cache memory.

In the related art such as Japanese Unexamined Patent Application Publications No. 2006-40011 and No. 2002-23966 noted above, until all write data transferred from a host computer to a channel adapter has been obtained, the write data is not transferred to the cache memory. Specifically, write data stored in distributed data buffer areas is transferred to the cache memory by starting a process for performing data verification based on a CRC code and data transfer to the cache memory each time for each divided unit of the write data has been obtained. Accordingly, write data is not transferred to the cache memory until all divided units of the write data have been obtained, and a time is required to wait for all the divided units of the write data to be obtained. Thus, the write data is not efficiently transferred from the host computer to the cache memory, resulting in processing time losses.

To overcome the foregoing problem, the aspect of the embodiment provides a data relay integrated circuit, a data relay apparatus, and a data relay method for efficiently transferring write data from a host computer to a cache memory to reduce processing time losses even if the write data is transferred from the host computer to a channel adapter and is stored in distributed data buffer areas.

To this end, according to an aspect of the aspect of the embodiment, there is provided a data relay integrated circuit in a data relay apparatus for relaying data transmitted and received between a computer apparatus and a storage apparatus via a temporary storage section, the data relay integrated circuit including a transmission section for temporarily accumulating, in an accumulation area, write data that is divided into predetermined units and that is sequentially transmitted from the computer apparatus to the storage apparatus, verifying the write data on the basis of first verification data attached to the write data, determining second verification data on the basis of the write data to add the second verification data to the write data, and transmitting the write data to the temporary storage section according to a transmission instruction issued from a control device of the data relay apparatus, wherein the transmission section sequentially transmits the write data that is divided into the predetermined units and that is sequentially transmitted from the computer apparatus to the storage apparatus to the temporary storage section in the predetermined units before verifying the write data on the basis of the first verification data in the accumulation area.

According to another aspect of the embodiment, there is provided a data relay apparatus for relaying data transmitted and received between a computer apparatus and a storage apparatus via a temporary storage section, the data relay apparatus including an accumulation section for temporarily accumulating, in an accumulation area, write data that is divided into predetermined units and that is sequentially transmitted from the computer apparatus to the storage apparatus; a first verification section for verifying the write data accumulated in the accumulation section on the basis of first verification data attached to the write data; an adding section for determining second verification data on the basis of the write data and adding the second verification data to the write data; and a transmission section for transmitting the write data to the temporary storage section according to the transmission instruction issued from a control device of the data relay apparatus, wherein the transmission section sequentially transmits the write data that is divided into the predetermined units and that is sequentially transmitted from the computer apparatus to the storage apparatus to the temporary storage section in the predetermined units before the write data is verified on the basis of the first verification data in the accumulation area.

According to still another aspect of the embodiment, there is provided a data relay method for relaying data transmitted and received between a computer apparatus and a storage apparatus via a temporary storage section, the data relay method including a transmitting step of temporarily accumulating, in an accumulation area, write data that is divided into predetermined units and that is sequentially transmitted from the computer apparatus to the storage apparatus, verifying the write data on the basis of first verification data attached to the write data, determining second verification data on the basis of the write data to add the second verification data to the write data, and transmitting the write data to the temporary storage section according to a transmission instruction issued from a control device of a data relay apparatus, wherein the transmitting step sequentially transmits the write data that is divided into the predetermined units and that is sequentially transmitted from the computer apparatus to the storage apparatus to the temporary storage section in the predetermined units before verifying the write data on the basis of the first verification data in the accumulation area.

According to the above-described aspects of the embodiment, data is sequentially transmitted to a temporary storage section in predetermined units without waiting for verification of the data based on first verification data. Therefore, the time required to wait for the verification based on the first verification data can be reduced, resulting in improved data relay processing performance through efficient processing.

In the aspect of the embodiment, further, the transmission section transmits to the temporary storage section all the predetermined units of the write data that is divided into the predetermined units and that is sequentially transmitted from the computer apparatus to the storage apparatus, and then verifies the write data on the basis of the first verification data in the accumulation area.

According to the aspect of the embodiment, the verification based on the first verification data and the transmission of the data to the temporary storage section in the predetermined units can be simultaneously performed. Therefore, different write data sequences transmitted from a computer apparatus can be transmitted to the temporary storage section through parallel processing.

In the aspect of the embodiment, further, the transmission section manages the predetermined units of the write data that is divided into the predetermined units and that is sequentially transmitted from the computer apparatus to the storage apparatus on the basis of identifiers having a one-to-one correspondence with the predetermined units of the write data, and includes a determination section for determining the second verification data for each of the identifiers each time one of the predetermined units of the write data is accumulated in the accumulation area; and a storage section for storing the second verification data determined by the determination section in association with each of the identifiers, wherein when the second verification data is added to one of the predetermined units of the write data that is associated with a given one of the identifiers, the second verification data stored in association with the given identifier in the storage section is added to the one predetermined unit.

According to the aspect of the embodiment, the data transmitted from the computer apparatus is transmitted to the temporary storage section in the predetermined units, and the second verification data is determined and added to the predetermined units of the data, as necessary. Therefore, the determination of the second verification data and the transmission of the data to the temporary storage section in the predetermined units can be simultaneously performed, resulting in improved data relay processing performance through efficiency processing.

In the aspect of the embodiment, further, the transmission section performs, according to a transmission instruction issued from the control device, a process for determining the second verification data for each of the identifiers each time one of the predetermined units of the write data that is divided into the predetermined units and that is sequentially transmitted from the computer apparatus to the storage apparatus is accumulated in the accumulation area and for sequentially transmitting the write data to the temporary storage section in the predetermined units before verifying the write data on the basis of the first verification data in the accumulation area.

According to the aspect of the embodiment, the determination of the second verification data and the transmission of the data transmitted from the computer apparatus to the temporary storage section in the predetermined units are simultaneously performed, and a process for adding the second verification data to the predetermined units of the data, as necessary, is performed according to a transmission instruction. Therefore, the processing can be efficiently performed to improve the data relay processing performance.

In the aspect of the embodiment, further, the second verification data includes a field check code (FCC) added to a field including at least one of the predetermined units, and a block check code (BCC) added to a block having a predetermined data length including a predetermined number of the fields, and the determination section determines the FCC and the BCC for each of the identifiers each time one of the predetermined units of the write data is accumulated in the accumulation area.

According to the aspect of the embodiment, the determination of an FCC and a BCC and the transmission of the data transmitted from the computer apparatus to the temporary storage section in the predetermined units are simultaneously performed. Therefore, the determination of an FCC and a BCC and the transmission of the data can be efficiently performed to improve the data relay processing performance.

According to the aspect of the embodiment, therefore, in a data relay apparatus for relaying data transmitted and received between a host computer and a RAID, transmission of write data from the host computer to a buffer of the data relay apparatus and transmission of the write data from the buffer to a cache memory of the data relay apparatus can be performed in parallel, and the advantage of improving the performance of the data relay apparatus for transmission of write data from the buffer to the cache memory can be achieved.

A data relay integrated circuit, a data relay apparatus, and a data relay method according to an exemplary the aspect of the embodiment will be described in detail hereinafter with reference to the accompanying drawings. The data relay apparatus of the aspect of the embodiment is an apparatus called a channel adapter for relaying data transmitted and received in transmission and reception of read/write data between a computer such as a mainframe host computer or an open system server and a RAID serving as a storage apparatus regardless of a difference in data format of the computer. The data relay integrated circuit serves as a send engine (SNE), which is a function implemented on an LSI chip called a protocol DMA chip mounted on the channel adapter.

The data is transmitted and received between the computer and the RAID via the channel adapter. The channel adapter transfers the data to a cache memory for temporary storage, thereby increasing the efficiency of data transmission and reception between the computer and the RAID.

In the aspect of the embodiment, it is assumed that variable-length data is divided into a plurality of frames according to a host interface standard such as fiber channel, FICON®, or FCLink and is transmitted from the host computer. In particular, the aspect of the embodiment overcomes the problem caused when in the related art, a protocol DMA chip transfers the transmitted data frames to a cache memory.

The problem with the related art is as follows. That is, a write data sequence that is divided and transmitted from the host computer using a single channel control work (CCW) (a defined control encoding work for controlling the operation of the channel adapter in input/output units) is temporarily stored in a buffer provided in the channel adapter.

As shown in FIG. 1, in the related art, a descriptor defining the operation of an SNE for transmitting write data from a buffer to a cache memory includes a “Group End” bit indicating the end of a group defined by a CCW, a “Field Start” bit indicating the start of a field, a “Field End” bit indicating the end of a field, and a “Block Start” bit indicating the start of a block (logical block addressing (LBA), as described below). In the example shown in FIG. 1, SNE descriptors for the same CCW need to be consecutive, like data units (1) to (3) and data units (4) to (6).

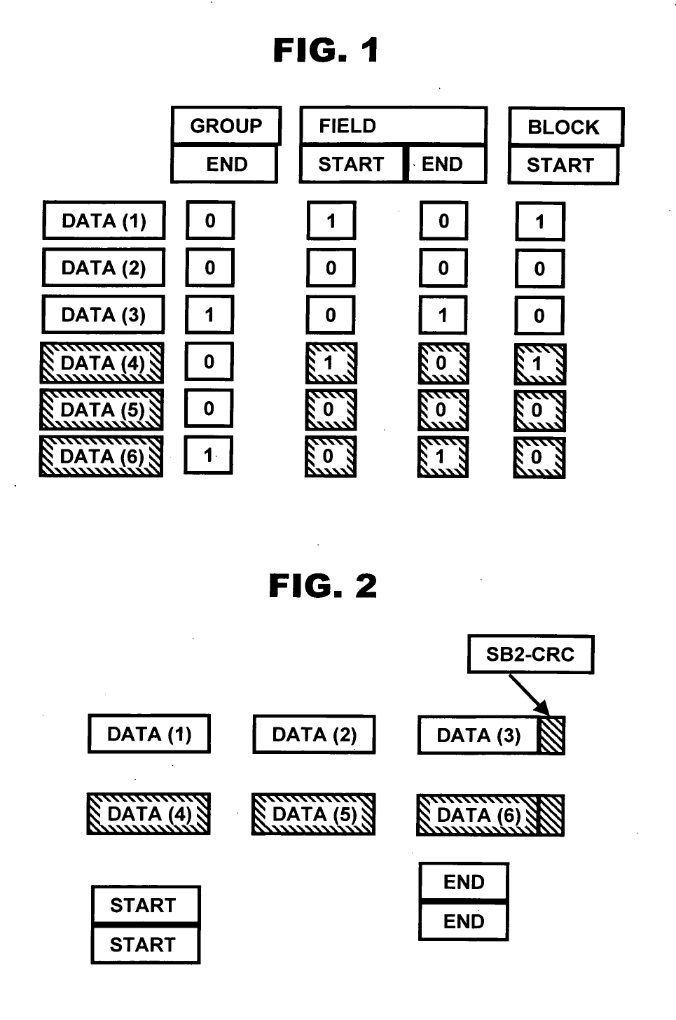

Each write data sequence transmitted using a single CCW has a CRC check code (SB2-CRC) for data verification. According to descriptors having the items described above, for example, when a first write data sequence that is divided into data units (1) to (3) and a second write data sequence that is divided into data units (4) to (6) are transmitted from the host computer, as shown in FIG. 2, data verification based on SB2-CRC codes is not performed until all the divided units of the same write data sequence such as the data units (1) to (3) or the data units (4) to (6) have been consecutively transmitted.

In the related art, therefore, as shown in FIG. 2, all the data units (1) to (3) are received and then verified on the basis of an SB2-CRC code associated therewith. Thereafter, all the data units (4) to (6) are received and then verified on the basis of an SB2-CRC code associated therewith. In this way, data verification based on an SB2-CRC code is required for each write data sequence transmitted according to a single CCW, and it is difficult to identify which write data sequence each divided unit belongs to. Therefore, it is difficult to perform data verification based on an SB2-CRC code if divided units of different write data sequences are alternately transmitted.

In the related art, further, the SNE is not activated until all divided units of the same write data sequence have consecutively been transmitted from the host computer. This method requires the SNE to be sequentially activated when write data having a field as long as, for example, 8 kilobytes or more is transferred to the cache memory. In addition, when write data with a long field is transferred to the cache memory, other processing is not performed until all divided units of the same write data sequence have been received by the buffer, resulting in low processing efficiency.

In the related art, moreover, if divided units of different write data sequences are alternately transmitted, there is a problem in that it is difficult to generate FCCs and BCCs, as described below, to be added to the write data sequences when the write data sequences are transferred to the cache memory.

Therefore, other processing is not performed for a period during which a long field of a write data sequence is transferred to the cache memory, leading to a great limitation on the performance for transmission of write data from the buffer to the cache memory.

To address the limitation, the SNE is improved so that even if all divided units of a write data sequence transmitted using a single CCW are not received by a buffer, each time one of the divided unit is received, the received divided unit is sequentially transmitted to a cache memory. Furthermore, to generate an FCC and a BCC by SNE with discontinuous descriptors, a group ID (GID) is defined in a descriptor of the SNE so that intermediate results of FCC and BCC calculation can be stored and read for each group ID. Therefore, the transmission of the write data from the host computer to the buffer and the transmission of the write data from the buffer to the SNE in the cache memory can be performed in parallel to realize improved performance for transmission of write data from the buffer to the cache memory.

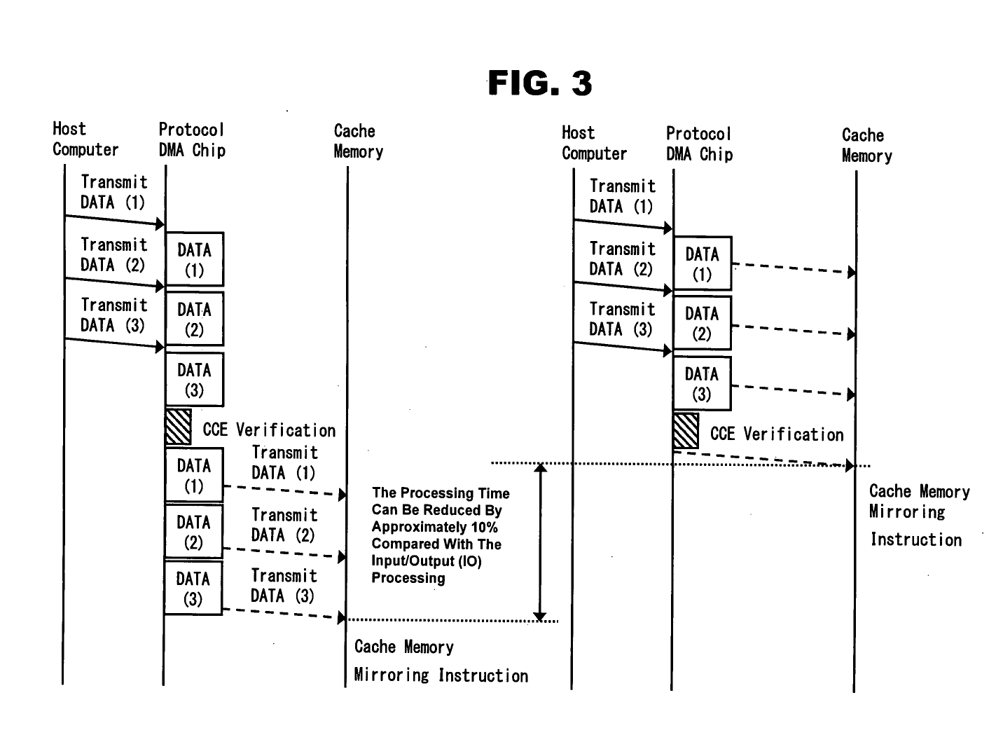

Before the description of the aspect of the embodiment, a feature of the aspect of the embodiment will be described. FIG. 3 is a diagram showing a feature of the aspect of the embodiment. As shown in FIG. 3, in the related art, when write data transmitted from a host computer to a protocol DMA chip is transmitted to a cache memory, data units (1) to (3) into which a single write data sequence is divided are sequentially transmitted from the host computer to the protocol DMA chip. The data units (1) to (3) have a verification code called SB2-CRC.

Upon receiving all the data units (1) to (3), a CRC check engine (CCE), which is an LSI function of the protocol DMA chip, verifies the data units (1) to (3) on the basis of the SB2-CRC code. When the CCE verification process successfully ends, the data units (1) to (3) are transmitted from the protocol DMA chip to the cache memory. After all the data units (1) to (3) have been transmitted, a cache-memory-mirroring instruction is transmitted from the protocol DMA chip to the cache memory.

According to the aspect of the embodiment, a process for transmitting the data units (1) to (3) from the protocol DMA chip to the cache memory after performing the CCE verification process is omitted. Therefore, the processing time can be reduced by approximately 10% compared with the input/output (IO) processing among the host computer, the protocol DMA chip, and the cache memory in the related art described above., and the efficiency of the IO processing between the protocol DMA chip and the cache memory is increased.

As shown in FIG. 3, according to a method of the aspect of the embodiment, data units (1) to (3) into which a single write data sequence is divided are sequentially transmitted from a host computer to a protocol DMA chip, and each time the protocol DMA chip receives one of the data units (1) to (3), the protocol DMA chip transmits the received data unit to the cache memory immediately thereafter before all the data units (1) to (3) have been obtained.

More specifically, the data unit (1) is transmitted from the host computer to the protocol DMA chip, and the protocol DMA chip transmits the data unit (1) to the cache memory immediately upon receiving the data unit (1). Then, the data unit (2) is transmitted from the host computer to the protocol DMA chip, and the protocol DMA chip transmits the data unit (2) to the cache memory immediately upon receiving the data unit (2). Further, the data unit (3) is transmitted from the host computer to the protocol DMA chip, and the protocol DMA chip transmits the data unit (3) to the cache memory immediately upon receiving the data unit (3). That is, before the completion of the data verification based on the SB2-CRC code of a write data sequence for the same CCW, the SNE is activated to transfer the write data sequence from a buffer to the cache memory.

Thereafter, the protocol DMA chip performs a CCE verification process on the data units (1) to (3). When the CCE verification process successfully ends, a cache-memory-mirroring instruction is transmitted from the protocol DMA chip to the cache memory.

In the aspect of the embodiment, therefore, write data is transmitted to the cache memory before all units into which the write data is divided have been received by the protocol DMA chip. Therefore, even if all the divided units of the write data reach the protocol DMA chip with a delay for some reason, an influence of the delay on the overall IO processing between the protocol DMA chip and the cache memory can be reduced.

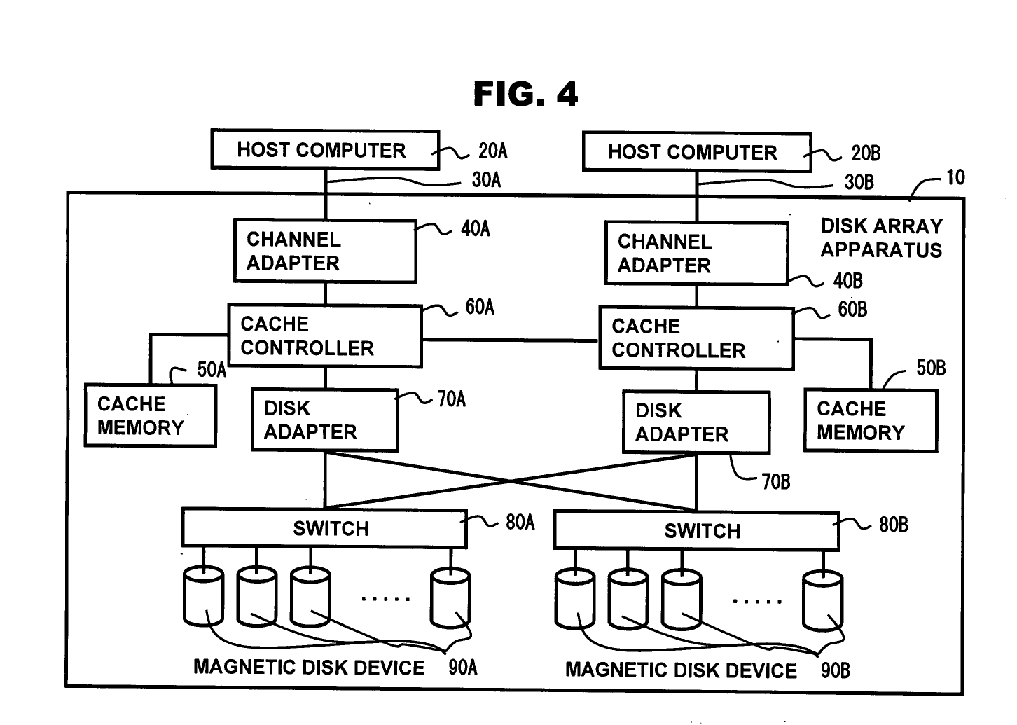

An exemplary the aspect of the embodiment will now be described with reference to FIGS. 4 to 10. FIG. 4 is a block diagram schematically showing a structure of a disk array apparatus 10 according to the exemplary the aspect of the embodiment. The disk array apparatus 10 is also referred to as a RAID. The disk array apparatus 10 is an apparatus serving as an external storage apparatus of a host computer 20 (including host computers 20A and 20B) as an external apparatus, and includes a disk array section for storing data and a disk array controller for controlling the disk array section.

The disk array section includes a plurality of magnetic disk devices 90 (including pluralities of magnetic disk devices 90A and 90B), and a switch 80 (including switches 80A and 80B) for switching among the plurality of magnetic disk devices 90. The magnetic disk devices 90 have different structures depending on RAID levels, which are generally defined according to data access speed and data redundancy.

For example, the magnetic disk devices 90 may be used for storing data, the magnetic disk device 90 may be used for mirroring the data stored in the magnetic disk devices 90, or the magnetic disk device 90 may be used for storing parity data generated for the data stored in the magnetic disk devices 90. In this manner, the magnetic disk devices 90 have different applications according to the RAID levels. The magnetic disk devices 90 store data in a fixed-length data format.

The disk array controller includes a channel adapter 40 (including channel adapters 40A and 40B) for performing interface control for the host computer 20, a cache memory 50 (including cache memories 50A and 50B) for temporarily storing data read from the magnetic disk devices 90, a cache controller 60 (including cache controllers 60A and 60B) for performing various types of control to read and write data and managing the cache memory 50, and a disk adapter 70 (including disk adapters 70A and 70B) for controlling each of the magnetic disk devices 90 according to an instruction issued by the cache controller 60 to read and write data.

The cache controller 60 has a function for, if data requested by the host computer 20 to be read does not resides on the cache memory 50, reading the data from the magnetic disk devices 90 to load it onto the cache memory 50 to permit the data to be read by the channel adapter 40.

If the capacity of the cache memory 50 is saturated, unnecessary data such as unused data and data that has not been accessed for a predetermined time since the last access is deleted to obtain an area for writing new data. The cache controller 60 also has a function for instructing the disk adapter 70 to write data written in the cache memory 50 into the magnetic disk devices 90 in response to a write request issued from the host computer 20.

The cache memory 50, which is a memory for accumulating data, has a function for storing data read from the magnetic disk devices 90 by the cache controller 60 or storing write data requested by the host computer 20 to be written.

The disk adapter 70 has a function for reading data from the magnetic disk devices 90 or writing data in the magnetic disk devices 90 according to an instruction issued from the cache controller 60.

The channel adapter 40 has a function for reading data corresponding to a read request made by the host computer 20 from the cache memory 50 to transfer the read data to the host computer 20, and writing data requested by the host computer 20 to be written into the cache memory 50. The channel adapter 40 and the host computer 20 are connected, for example fiber channel 30.

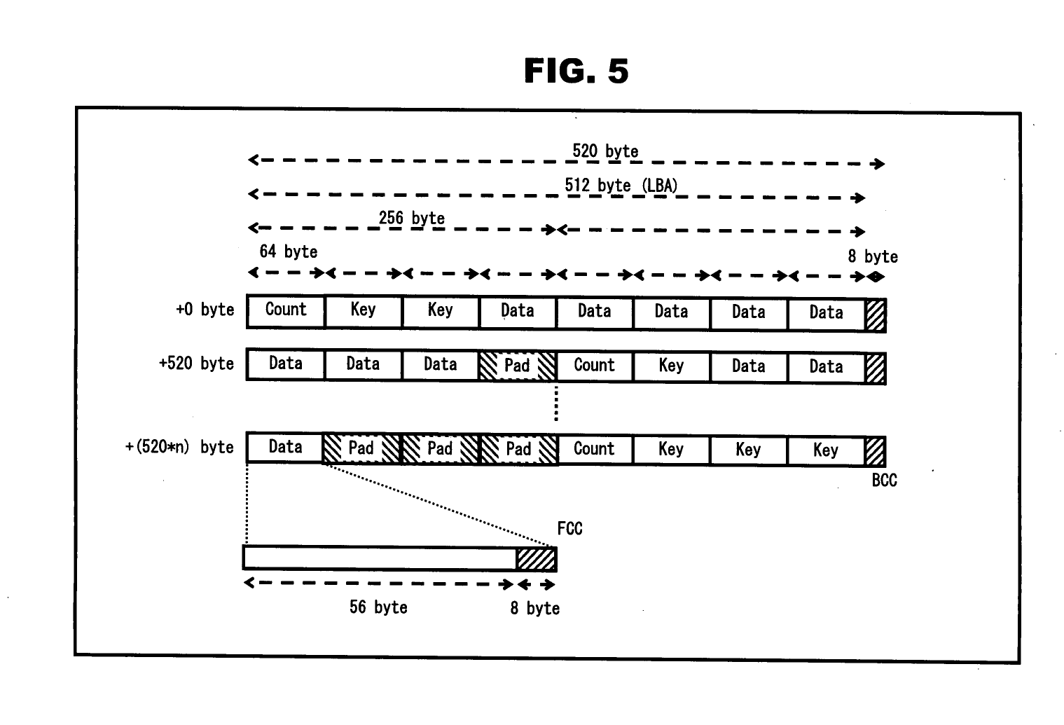

In the structure described above, a data access method according to the aspect of the embodiment can be used for writing data from the channel adapter 40 to the cache memory 50. A format conversion operation and a check code during data transfer between the channel adapter 40 and the cache memory 50 will now be described. FIG. 5 is a diagram showing a data format used for transferring data to the cache memory 50. That is, the cache memory 50 stores data in the format shown in FIG. 5.

When data with a variable-length data format is stored in a fixed-length data format, a count key data (CKD) format is used as the variable-length data format. A record with the CKD format is composed of a plurality of LBAs with a record length of 512 bytes, each LBA having an 8-byte BCC added to the end thereof. The record with the CKD format includes three portions, i.e., count, key, and data portions. The count portion has a fixed length of 64 bytes, and includes information concerning the address and data length of the record. The key portion has a variable length in units of 64 bytes, and is used by an operating system to identify the record. The data portion has a variable length in units of 64 bytes, and is an area for storing user data. The count, key, and data portions are referred to as fields.

In the magnetic disk devices 90, variable-length data passed from the host computer 20 is managed in logical blocks with a fixed length. The fixed length is 512 bytes. The cache memory 50 contains data read from the magnetic disk devices 90, which is error-checked for every 512-byte logical block called LBA, and an 8-byte error check code (BCC) indicating a result of the error check, which is added to the end of each of the LBAs. Thus, data written in the cache memory 50 is configured such that an 8-byte BCC for error protection is sequentially added to each LBA, resulting in a data length with a total of 520 bytes.

An 8-byte error check code (FCC) calculated for error protection is also added to each field. The 8-byte FCC is added to the end of each field. Therefore, each LBA includes the count, key, and data portions each having an 8-byte FCC, and has a length of 512 bytes.

Preferably, each BCC is generated as a result of calculation using the overall data of each LBA, and each FCC is generated as a result of calculation using the overall data of each field. For example, a CRC method may be used for error check and CRC codes generated by the CRC method may be used. However, the aspect of the embodiment is not limited thereto, and any other code such as Hamming codes may be used.

When data with a variable-length data format is stored in a fixed-length data format in units of LBAs, an end portion of the variable-length data appears in units of half the data length of the LBAs, i.e., 256 bytes. That is, when data with a variable-length data format is formatted into fixed-length records in units of LBAs and the record length of the remaining portion in the last LBA is not less than 256 bytes, padding data is embedded in bytes up to the 256th byte, and new variable-length data is stored starting from the 257th byte from the beginning of the LBA. When data with a variable-length data format is formatted into fixed-length records in units of LBAs and the record length of the remaining portion in the last LBA is less than 256 bytes, padding data is embedded up to the end of the LBA, and new variable-length data is stored starting from the beginning of the next LBA.

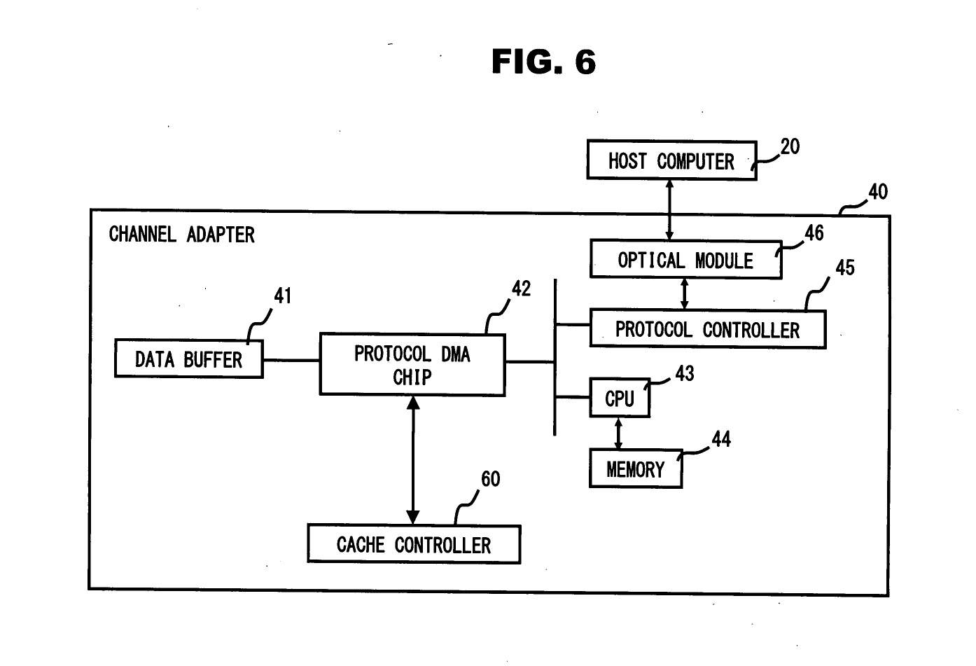

Next, a structure of a channel adapter according to the exemplary the aspect of the embodiment will be described. FIG. 6 is a block diagram showing an internal structure of a channel adapter according to the exemplary the aspect of the embodiment. The channel adapter 40 includes a data buffer 41, a protocol DMA chip 42 serving as an LSI chip, a CPU 43, a memory 44, a protocol controller 45, and an optical module 46. The protocol DMA chip 42, the CPU 43, and the protocol controller 45 are connected to one another via a predetermined bus so that data can be transferred to one another.

The protocol DMA chip 42 serves as an interface with the cache controller 60. The protocol DMA chip 42 is placed between the host computer 20 that issues an access request, such as a data write request, and the cache memory 50, and has a DMA function for transferring data between the host computer 20 and the cache memory 50 without intervention of the CPU 43 while buffering the data in the data buffer 41. The protocol DMA chip 42 communicates with the cache controller 60 according to an instruction from the CPU 43.

In FIG. 6, the host computer 20 and the disk array apparatus 10 are connected via an optical fiber by way of example. A side on which the protocol DMA chip 42 is connected to the host computer 20 includes the optical module 46 configured to convert an optical signal transmitted from the host computer 20 into an electrical signal and to convert an electrical signal from the disk array apparatus 10 into an optical signal, and the protocol controller 45 configured to control a protocol of a fiber channel used for connection between the protocol DMA chip 42 and the host computer 20.

The CPU 43 is an LSI component including a processor for controlling the overall operation of the channel adapter 40, and a memory interface section. The CPU 43 includes a data processing block (not shown) serving as a functional module relating to a data writing method. The data processing block has a function for generating a descriptor necessary for writing new data with the CKD format in the cache memory 50.

For example, the CPU 43 has a function for generating a descriptor for writing new data with the CKD format in the cache memory 50. The descriptor describes a procedure necessary for executing a data access process performed by the protocol DMA chip 42.

The memory 44 is a storage device for storing a descriptor etc., used in the operation of the CPU 43, and is connected to the CPU 43. The descriptor includes an identifier of data transmitted and received between the host computer 20 and the cache memory 50. The memory 44 includes a descriptor storage area (not shown) for storing the descriptor generated by the data processing block of the CPU 43.

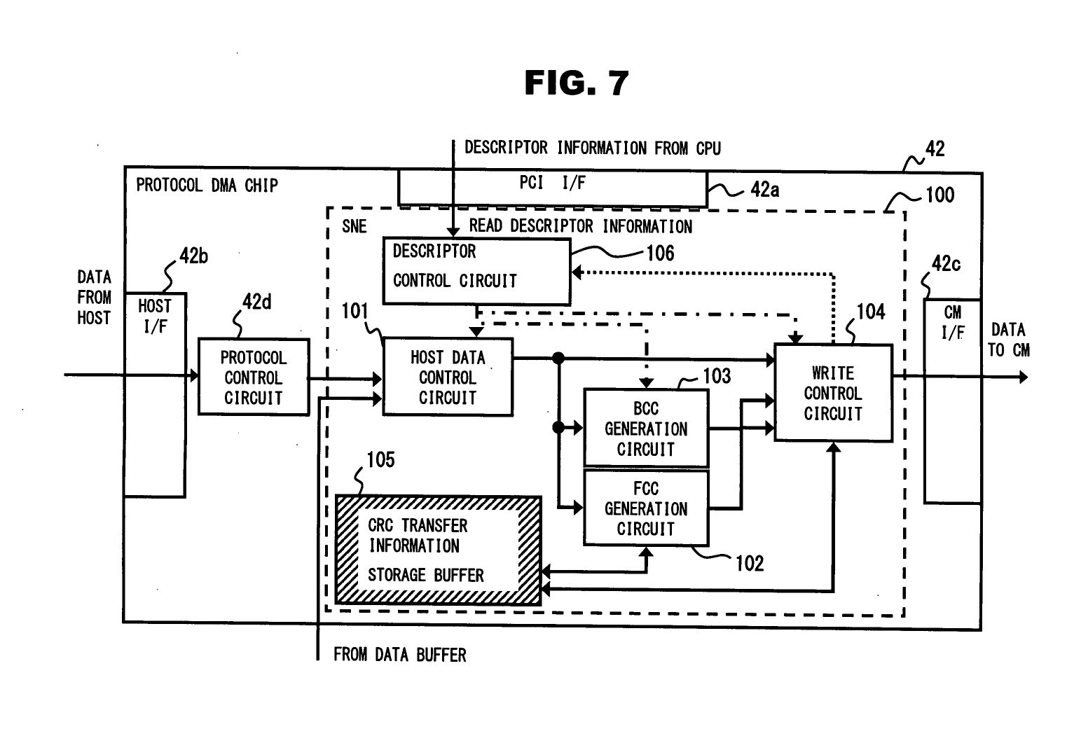

Next, a structure of the protocol DMA chip 42 shown in FIG. 6 will be described. FIG. 7 is a block diagram showing a structure of a protocol DMA chip according to the exemplary the aspect of the embodiment. As shown in FIG. 7, the protocol DMA chip 42 includes an SNE 100, a peripheral component interconnect interface (PCI I/F) 42a, a host I/F 42b, a controller module (CM) I/F 42c, and a protocol control circuit 42d. The protocol DMA chip 42 further includes a function section (serving as a CCE) for verifying transmission data transmitted from the host computer to the RAID, which is temporarily stored in the data buffer 41, on the basis of SB2-CRC codes, a function section for transmitting a cache-memory-mirroring instruction, a function section for performing a process for reading data from the cache memory 50, and a function section (serving as a receive engine) for reading the descriptor stored in the memory 44 by the data processing block of the CPU 43 and notifying relevant processing sections of the read descriptor information, a description of which is omitted.

The protocol DMA chip 42 includes the PCI I/F 42a serving as an interface with the CPU 43, the host I/F 42b serving as an interface with the host computer 20, the CM I/F 42c serving as an interface with the cache controller 60, the protocol control circuit 42d for controlling a fiber channel protocol used for connection with the host computer 20, and the SNE 100 for performing data processing to the cache memory 50 in response to a data write request from the host computer 20.

The SNE 100 receives the descriptor information stored in the memory 44 from the CPU 43 via the PCI I/F 42a serving as an interface. The SNE 100 further obtains write data to be written in the magnetic disk devices 90, which is temporarily stored in the data buffer 41, and transmits the write data to the cache memory 50 via the CM I/F 42c according to the above descriptor information.

The SNE 100 is a module for transferring new write data from the host computer 20 to the cache memory 50, and includes a host data control circuit 101 for reading data to be written in the cache memory 50, an FCC generation circuit 102 for generating an FCC for each field of the read data, a BCC generation circuit 103 for generating a BCC for each logical block of the read data, a write control circuit 104 for generating logical-block-length data to be written in the cache memory 50 from the data transmitted from the host data control circuit 101, the FCC generation circuit 102, and the BCC generation circuit 103, and controlling writing in the cache memory 50, a CRC transfer information storage buffer 105, and a descriptor control circuit 106.

The host data control circuit 101 has a function for selectively reading data from the data buffer 41 in units of fields according to a data-write descriptor. Specifically, if the data-write descriptor indicates writing of new data, the host data control circuit 101 performs an operation for reading the write data stored in the data buffer 41, and passing the data to the FCC generation circuit 102, the BCC generation circuit 103, and the write control circuit 104.

The FCC generation circuit 102 has a function for calculating and generating an FCC for each field of the data delivered from the data buffer 41 through the host data control circuit 101 on the basis of data-write descriptor, and temporarily storing the generated FCC in the CRC transfer information storage buffer 105.

The BCC generation circuit 103 has a function for calculating and generation a BCC in units of logical blocks (LBAs) for the data passed from the host data control circuit 101 on the basis of data-write descriptor, and temporarily storing the generated BCC in the CRC transfer information storage buffer 105.

The write control circuit 104 has a function for generating an LBA to be written in the cache memory 50 from the data delivered from the host data control circuit 101 on the basis of data-write descriptor.

Specifically, in the disk array apparatus 10 according to the exemplary the aspect of the embodiment, since data is managed in 512-byte fixed-length LBAs, when each divided data segment from the host data control circuit 101 has a length of 512 bytes, a BCC is added to the end of the data segment according to designation of the data-write descriptor. When new data is written, an FCC is added to a predetermined position of a field write block including the end of each field according to designation of the data-write descriptor.

Further, the write control circuit 104 transmits a data transfer completion notification to the descriptor control circuit 106 when data transmission to the cache memory 50 is completed.

The CRC transfer information storage buffer 105 stores intermediate results of FCC and BCC calculation determined by the FCC generation circuit 102 and the BCC generation circuit 103 in association with each of identifiers identifying a write data sequence that is divided into units and that is sequentially transmitted from the host computer 20. The intermediate results of FCC and BCC calculation is determined by the FCC generation circuit 102 and the BCC generation circuit 103 for each of the divided units of the write data sequence on the basis of the divided unit. Then, the up-to-date FCC or BCC stored in the CRC transfer information storage buffer 105 is read by the write control circuit 104 according to designation of the data-write descriptor, and is added to the data to be transferred to the cache memory 50. The resulting data is then transmitted to the cache memory 50.

This is because, for example, in a case where divided units of the write data sequence up to the second divided unit have been transmitted, an FCC or BCC based on the data of up to the second divided unit can be determined on the basis of an intermediate result of FCC or BCC calculation, which is determined on the basis of the data of up to the first divided unit transmitted preceding the second divided unit, and an FCC or BCC based on the second divided unit.

The CRC transfer information storage buffer 105 further stores addresses at which the write control circuit 104 writes divided units of a write data sequence in the cache memory 50. Such address information allows the write control circuit 104 to write a write data sequence divided into divided units in consecutive areas of the cache memory 50.

The descriptor control circuit 106 has a function for reading the descriptor stored in the memory 44 by the data processing block of the CPU 43, and notifying the host data control circuit 101, the FCC generation circuit 102, the BCC generation circuit 103, and the write control circuit 104 of the descriptor information read to a relevant processing section.

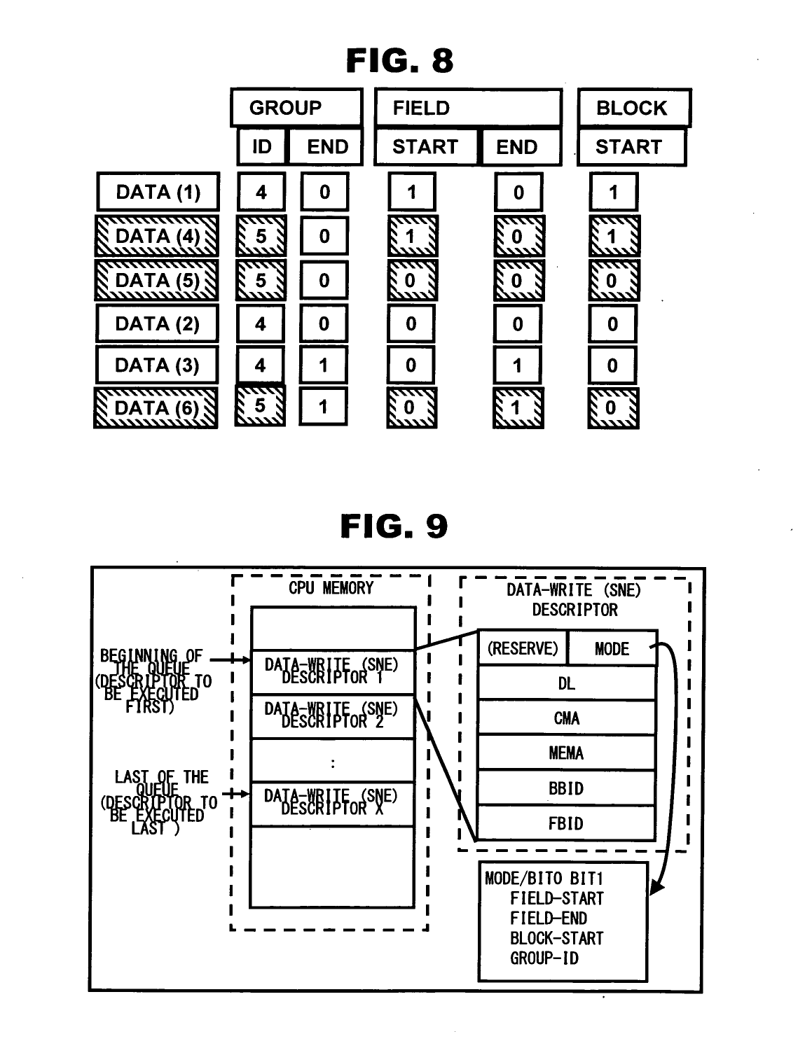

Next, an example of a setting of a descriptor according to the exemplary the aspect of the embodiment will be described. FIG. 8 is a diagram showing an example of a setting of a descriptor according to the exemplary the aspect of the embodiment. The descriptor shown in FIG. 8 is a data-write descriptor. In FIG. 8, it is assumed that data units (1) to (3) into which a first write data sequence is divided have a group ID (GID) of “4”, and data units (4) to (6) into which a second write data sequence is divided has a group ID of “5”. Each of the group IDs has an information length of 5 bits, and corresponds to the identifier identifying a transmission data sequence described above.

Since each group ID is 5-bit information, a total of 64 groups can be simultaneously managed.

It is assumed that the data units (1) to (6) have reached the protocol DMA chip 42 from the host computer 20 in an order of the data units (1), (4), (5), (2), (3), and (6). Since the data unit (1) has a group ID of “4”, and has a “Group End” bit value of “0” because it is not the last data unit in the first write data sequence. Further, the data unit (1) has “Field Start” and “Field End” bit values of “1” and “0”, respectively, because it is the start data unit of the field. If the “Field Start” bit value is “1”, the intermediate result of FCC calculation determined in association with the corresponding group ID, which is stored in the CRC transfer information storage buffer 105, is initialized.

The data unit (1) further has a “Block Start” bit value of “1” because it is also the start data unit of the block (i.e., LBA). If the “Block Start” bit value is “1”, the intermediate result of BCC calculation determined in association with the corresponding group ID, which is stored in the CRC transfer information storage buffer 105, is initialized. That is, when the data unit (1) is received by the SNE 100 of the protocol DMA chip 42, the FCC and BCC associated with a group ID of “4” are initialized.

Likewise, the data unit (4) has a group ID of “5”, and has a “Group End” bit value of “0” because it is not the last data unit of the second write data sequence. Further, the data unit (4) has “Field Start” and “Field End” bit values of “1” and “0”, respectively, because it is the start data unit of the field. The data unit (4) further has a “Block Start” bit value of “1” because it is also the start data unit of the block.

The data unit (5) has a group ID of “5”, and has a “Group End” bit value of “0” because it is not the last data unit of the second write data sequence. Further, the data unit (5) has “Field Start” and “Field End” bit values of “0” because it is not the start data unit or end data unit of the field. The data unit (5) further has a “Block Start” bit value of “0” because it is not the start data unit of the block.

The data unit (2) has a group ID of “4”, and has a “Group End” bit value of “0” because it is not the last data unit of the first write data sequence. Further, the data unit (2) has “Field Start” and “Field End” bit values of “0” because it is not the start data unit or end of data unit of the field. The data unit (2) further has a “Block Start” bit value of “0” because it is not the start data unit of the block.

The data unit (3) has a group ID of “4”, and has a “Group End” bit value of “1” because it is the last data unit of the first write data sequence. Further, the data unit (3) has “Field Start” and “Field End” bit values of “0” and “1”, respectively, because it is not the start data unit but the end data unit of the field. If the “Field End” bit value is “1”, the intermediate result of FCC calculation determined in association with the corresponding group ID, which is stored in the CRC transfer information storage buffer 105, and the FCC calculated on the basis of the data unit (3) are added to the end of the write data to be written in the cache memory 50 including up to the data unit (3). The data unit (3) further has a “Block Start” bit value of “0” because it is not the start data unit of the block.

The data unit (6) has a group ID of “5”, and has a “Group End” bit value of “1” because it is the last data unit of the second write data sequence. Further, the data unit (6) has “Field Start” and “Field End” bit values of “0” and “1”, respectively, because it is not the start data unit but is the end data unit of the field. The data unit (6) further has a “Block Start” bit value of “0” because it is not the start data unit of the block.

In this manner, each group ID is defined so that an FCC or BCC can be calculated for each of divided units of transmission data that are transmitted according to discontinuous descriptors, thereby storing and reading FCCs and BCCs on a group-by-group basis. Further, the “Group End”, “Field Start”, “Field End”, and “Block Start” items are separately specified, thereby determining whether to add an FCC for each divided data unit. For a divided unit for which it is determined by a descriptor that an FCC needs to be added, the write control circuit 104 reads the up-to-date FCC stored in the CRC transfer information storage buffer 105, and adds the read FCC to the end of the data.

A BCC is added to write data stored in the cache memory 50 when the write control circuit 104 determines that the data length of the write data is 512 bytes, rather than according to designation of a descriptor.

Next, the format of the descriptor shown in FIG. 8 will be described. FIG. 9 is a diagram showing an example of a descriptor format according to the exemplary the aspect of the embodiment. As shown in FIG. 9, data-write descriptors used by the SNE 100 are stored in a queue in a CPU memory of the CPU 43. As shown in FIG. 9, data-write (SNE) descriptor 1, which is a descriptor to be executed first, is placed at the beginning of the queue. Data-write (SNE) descriptor 2, etc., are subsequently queued according to an order in which they are to be executed. Data-write (SNE) descriptor x is queued as a descriptor to be executed last. The descriptors that are created in the memory 44 by firmware of the channel adapter 40 are read by the descriptor control circuit 106 according to the order of the queue. Data is transferred from the data buffer 41 to the cache memory 50 according to designation of the descriptors.

As shown in FIG. 9, the data-write (SNE) descriptor format includes a “mode” portion subsequent to a portion reserved in a predetermined area at the beginning, a “dl” portion for specifying a data length, a “cma” portion for specifying an address of a cache memory as a transfer destination, a “mema” portion for specifying an address of a data buffer as a transfer source, a “bbid” portion for specifying an ID of a BCC, and a “fbid” portion for setting an ID of an FCC.

The “mode” portion includes a “bit0” value indicating whether or not to generate an FCC, a “bit1” value indicating whether or not to generate a BCC, a “Field-Start” value indicating the start of a field, a “Field-End” value indicating the end of a field, a “Block-Start” value indicating the start of a block (LBA), and a “Group-ID” value indicating a group ID. The “bit0” and the “bit1” values are typically set to “1” (indicating that an FCC or a BCC is to be generated).

In the exemplary the aspect of the embodiment, by newly adding the “Group-ID” value to a descriptor, even if divided units of write data are not consecutively transmitted from the host computer 20 to the protocol DMA chip 42, the divided units can be transferred to the cache memory 50, while an FCC and a BCC is calculated for the write data, immediately after the divided units are received.

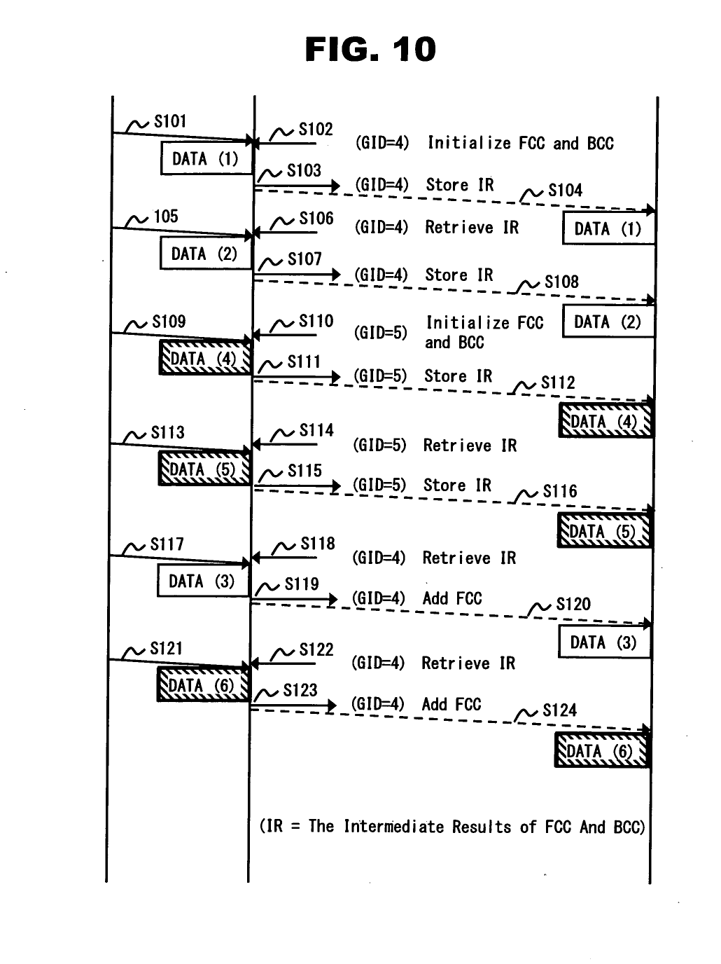

Next, a data transfer process based on a plurality of CCWs according to the exemplary the aspect of the embodiment will be described. FIG. 10 is a sequence diagram showing a data transfer process based on a plurality of CCWs according to the exemplary the aspect of the embodiment. Here, it is assumed that data units (1) to (3) belong to a write data sequence with a group ID of “4” and the data unit (3) is set as the end of a field. It is also assumed that data units (4) to (6) have a group ID (GID) of “5” and the data unit (6) is set as the end of a field. Although a BCC is added to write data at intervals of 512 bytes, a description of this process is omitted.

As shown in FIG. 10, first, the host computer 20 transmits the data unit (1) to the protocol DMA chip 42 (step S101). Upon receiving the data unit (1), the protocol DMA chip 42 initializes an FCC and BCC associated with GID=4; which are stored in the CRC transfer information storage buffer 105 (step S102). Then, the FCC generation circuit 102 and BCC generation circuit 103 of the protocol DMA chip 42 calculate an FCC and BCC associated with GID=4 on the basis of the data unit (1), and stores intermediate results of the FCC and BCC calculation in the CRC transfer information storage buffer 105 (step S103). Then, the protocol DMA chip 42 transfers the data unit (1) to the cache memory 50 (step S104).

Subsequently, the host computer 20 transmits the data unit (2) to the protocol DMA chip 42 (step S105). Upon receiving the data unit (2), the protocol DMA chip 42 retrieves the intermediate results of the FCC and BCC calculation for GID=4, which are stored in the CRC transfer information storage buffer 105 (step S106). Then, the FCC generation circuit 102 and BCC generation circuit 103 of the protocol DMA chip 42 calculate an FCC and BCC associated with GID=4 on the basis of the data unit (2) and the retrieved intermediate results of calculation of the FCC and BCC, and stores intermediate results of the FCC and BCC calculation in the CRC transfer information storage buffer 105 (step S107). Then, the protocol DMA chip 42 transfers the data unit (2) to the cache memory 50 (step S108).

Subsequently, the host computer 20 transmits the data unit (4) to the protocol DMA chip 42 (step S109). Upon receiving the data unit (4), the protocol DMA chip 42 initializes an FCC and BCC associated with GID=5, which are stored in the CRC transfer information storage buffer 105 (step S110). Then, the FCC generation circuit 102 and BCC generation circuit 103 of the protocol DMA chip 42 calculate an FCC and BCC associated with GID=5 on the basis of the data unit (4), and stores intermediate results of the FCC and BCC calculation in the CRC transfer information storage buffer 105 (step S111). Then, the protocol DMA chip 42 transfers the data unit (4) to the cache memory 50 (step S112).

Subsequently, the host computer 20 transmits the data unit (5) to the protocol DMA chip 42 (step S113). Upon receiving the data unit (5), the protocol DMA chip 42 retrieves the intermediate results of the FCC and BCC calculation for GID=5, which are stored in the CRC transfer information storage buffer 105 (step S114). Then, the FCC generation circuit 102 and BCC generation circuit 103 of the protocol DMA chip 42 calculate an FCC and BCC associated with GID=5 on the basis of the data unit (5) and the retrieved intermediate results of the FCC and BCC calculation, and stores intermediate results of the FCC and BCC calculation in the CRC transfer information storage buffer 105 (step S115). Then, the protocol DMA chip 42 transfers the data unit (5) to the cache memory 50 (step S116).

Subsequently, the host computer 20 transmits the data unit (3) to the protocol DMA chip 42 (step S117). Upon receiving the data unit (3), the protocol DMA chip 42 retrieves the intermediate results of the FCC and BCC calculation for GID=4, which are stored in the CRC transfer information storage buffer 105 (step S118). Then, the FCC generation circuit 102 and BCC generation circuit 103 of the protocol DMA chip 42 calculate an FCC and BCC associated with GID=4 on the basis of the data unit (3) and the retrieved intermediate results of the FCC and BCC calculation, and stores the obtained BCC, which is an intermediate result of the BCC calculation, in the CRC transfer information storage buffer 105 while adding the obtained FCC to the data unit (3) (step S119). Then, the protocol DMA chip 42 transfers the data unit (3) to the cache memory 50 (step S120).

Subsequently, the host computer 20 transmits the data unit (6) to the protocol DMA chip 42 (step S121). Upon receiving the data unit (6), the protocol DMA chip 42 retrieves the intermediate results of the FCC and BCC calculation for GID=5, which are stored in the CRC transfer information storage buffer 105 (step S122). Then, the FCC generation circuit 102 and BCC generation circuit 103 of the protocol DMA chip 42 calculate an FCC and BCC associated with GID=5 on the basis of the data unit (6) and the retrieved intermediate results of the FCC and BCC calculation, and stores the obtained BCC, which is an intermediate result of the BCC calculation, in the CRC transfer information storage buffer 105 while adding the obtained FCC to the data unit (6) (step S123). Then, the protocol DMA chip 42 transfers the data unit (6) to the cache memory 50 (step S124).

Accordingly, FCCs and BCCs can be calculated for each GID. Therefore, even if divided units of different write data sequences are alternately transmitted, a plurality of FCCs and BCCs can be simultaneously calculated. Further, write data transmitted from the host computer 20 to the protocol DMA chip 42 is transferred to the cache memory 50 immediately after the write data has reached the protocol DMA chip 42. Therefore, the transmission of the write data from the host computer to the buffer and the transmission of the write data from the buffer to the SNE in the cache memory can be performed in parallel, thereby realizing improved performance for the transmission of the write data from the buffer to the cache memory over the related art.

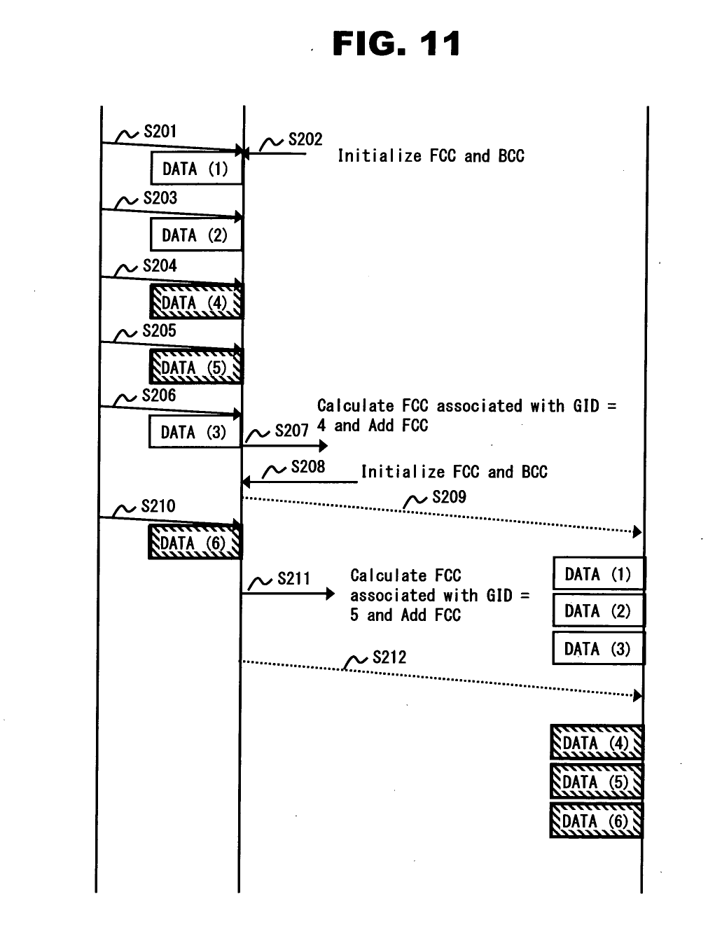

A data transfer process based on a plurality of CCWs in the related art will be described hereinafter. FIG. 11 is a sequence diagram showing a data transfer process based on a plurality of CCWs in the related art. Here, it is assumed that data transmitted from a host computer can be identified by a GID, data units (1) to (3) belong to a write data sequence with a group ID of “4”, and the data unit (3) is set as the end of a field. It is also assumed that data units (4) to (6) have a group ID (GID) of “5” and the data unit (6) is set as the end of a field. Although a BCC is added to write data at intervals of 512 bytes, a description of this process is omitted.

As shown in FIG. 11, first, the data unit (1) is transmitted from the host computer to a protocol DMA chip (step S201). Upon receiving the data unit (1), the protocol DMA chip initializes FCC and BCC values in a predetermined storage area (step S202).

Subsequently, the data units (2), (4), (5), and (3) are transmitted from the host computer to the protocol DMA chip (steps S203, S204, S205, and S206). When the processing of step S206 ends, the data units (1) to (3) have been received by the protocol DMA chip. Thus, the protocol DMA chip calculates an FCC associated with GID=4, and adds the FCC to the end of the data unit (3) (step S207). Then, the protocol DMA chip initializes the FCC and BCC values in the predetermined storage area (step S208). Then, the protocol DMA chip transmits the data units (1) to (3) to the cache memory in the stated order (step S209).

Subsequently, the data unit (6) is transmitted from the host computer to the protocol DMA chip (step S210). When the processing of step S210 ends, the data units (4) to (6) have been received by the protocol DMA chip. Thus, the protocol DMA chip calculates an FCC associated with GID=5 and adds the FCC to the end of the data unit (6) (step S211). Then, the protocol DMA chip transmits the data units (4) to (6) to the cache memory in the stated order (step S212).

In the related art, therefore, only an FCC and BCC of a single write data sequence can be calculated at a time. Therefore, an FCC (or BCC) is not generated or added until data of all divided units of the same write data sequence has been received. Further, until all divided units of a write data sequence have been received by a data buffer of the protocol DMA chip, an SNE is not activated to transmit the write data sequence to the cache memory, resulting in low transmission efficiency. This also causes a delay of transmission of write data from the protocol DMA chip to the cache memory, resulting in low efficiency.

While an exemplary the aspect of the embodiment of has been described, the aspect of the embodiment is not limited thereto, and a variety of exemplary the aspect of the embodiments can be conceived within a technical scope defined in the appended claims. The advantages disclosed in the foregoing exemplary the aspect of the embodiment are not to be construed as limited thereby.

Of the processes described above in the exemplary the aspect of the embodiment, the whole or a part of a process that has been described as being performed automatically may be performed manually, or the whole or a part of a process that has been described as being performed manually may be performed automatically using a known method. In addition, information including the processing procedures, control procedures, specific names, and various types of data and parameters, as described above in the exemplary the aspect of the embodiment, can be arbitrarily changed unless stated otherwise.

The components of the apparatuses shown in the figures are functional and conceptual, and may not necessarily be configured physically in the manner shown in the figures. In other words, specific configurations of distributed or integrated components in the illustrated apparatuses are not limited to those shown in the figures. Therefore, all or a part of the components can be functionally or physically distributed or integrated in arbitrary units according to various loads or use conditions.

Furthermore, all or any part of processing functions achieved by the illustrated apparatuses may be realized by a CPU (or a micro computer such as a micro processing unit (MPU) or a micro controller unit (MCU)) and a program interpreted and executed by the CPU, or may be realized as hardware using wired logic.

The aspect of the embodiment is useful for efficiently transferring write data from a host computer to a cache memory to reduce processing time losses even when the write data is transferred from the host computer to a channel adapter and is stored in distributed data buffer areas.

What is claimed is:

1. A data relay apparatus for transferring writing data and an associated check code sequentially sent from a host into a memory device, said writing data containing a plurality of fields classified by the kind of information in said writing data, comprising:
a memory for storing said writing data and said check code for checking an error of said writing data;
a calculating module for calculating said check code to determine whether the writing data sent from the host contains an error; and
a transfer module for transferring the writing data into the memory, the transferring of the writing data into the memory being initiated before determination by the calculating module.

2. The apparatus according to claim 1, wherein said calculating module calculates field check code for checking an error of said field corresponding to said field and add said field check code to said writing data.

3. The apparatus according to claim 1, wherein said transfer module transfers said writing data divided into predetermined size, said calculating module calculates block check code for checking an error of said writing data divided into predetermined size and add said block check code to said writing data.

4. The apparatus according to claim 1, further comprising, a plurality of a memory device,
wherein said memory device copies said writing data among said plurality of memory when said calculating module verifies said writing data.

5. A method of an apparatus for transferring writing data and an associated check code sequentially sent from a host into a memory device, said writing data containing a plurality of fields classified by the kind of information in said writing data, comprising:
storing said writing data and said check code for checking an error of said writing data into a memory;
calculating said check code to determine whether the writing data sent from the host contains an error; and
transferring the writing data into the memory, the transferring of the writing data into the memory being initiated before determination by the calculating module.

6. The method according to claim 5, wherein said the step of calculating comprises calculating field check code for checking an error of said field corresponding to said field and add said field check code to said writing data.

7. The method according to claim 5, wherein said the step of transferring comprises transferring said writing data divided into predetermined size, said the step of calculating comprises calculating block check code for checking an error of said writing data divided into predetermined size and add said block check code to said writing data.

8. The method according to claim 5, further comprising, a plurality of a memory device,
wherein said memory device copies said writing data among said plurality of memories on the basis of a verification of said writing data in said the step of calculating.

9. A data relay integrated circuit in a data relay apparatus for transferring writing data and an associated check code sequentially sent from a host into a memory device, said writing data containing a plurality of fields classified by the kind of information in said writing data, comprising:
a memory for storing said writing data and said check code for checking an error of said writing data;
a calculating module for calculating said check code to determine whether the writing data sent from the host contains an error; and
a transfer module for transferring the writing data into the memory, the transferring of the writing data into the memory being initiated before determination by the calculating module.

10. The circuit according to claim 1, wherein said calculating module calculates field check code for checking an error of said field corresponding to said field and add said field check code to said writing data.

11. The circuit according to claim 1, wherein said transfer module transfers said writing data divided into predetermined size, said calculating module calculates block check code for checking an error of said writing data divided into predetermined size and add said block check code to said writing data.

12. The circuit according to claim 1, further comprising, a plurality of a memory device,
wherein said memory device copies said writing data among said plurality of memory when said calculating module verifies said writing data.
